(19) United States
(12) Patent Application Publication
(10) Pub. No.: US 2026/0241487 A1
(43) Pub. Date: Aug. 20, 2026

(54) LASER BONDING DEVICE AND LASER BONDING METHOD

(71) Applicant: Samsung Display Co., Ltd., Yongin-si (KR)

(72) Inventors: Tae Hee LEE, Yongin-si (KR); Jae Gwang UM, Yongin-si (KR); Moon Won CHANG, Yongin-si (KR); Ki Su JIN, Yongin-si (KR)

(21) Appl. No.: 19/395,604

(22) Filed: Nov. 20, 2025

(30) Foreign Application Priority Data
Feb. 19, 2025 (KR) 10-2025-0021447

(51) Int. Cl. B23K 26/21

(52) U.S. Cl. CPC B23K 26/21

(57) ABSTRACT

A laser bonding device and a laser bonding method are provided. The laser bonding device includes: a stage configured to support a first substrate; a pressure module configured to fix a plurality of elements on the first substrate; a laser irradiator configured to irradiate a laser beam to a conductive bonding pattern located between the first substrate and the plurality of elements; and a mask located on the first substrate and having openings overlapping the plurality of elements, wherein the plurality of elements includes at least one of a light emitting element, an integrated circuit, or a driving circuit, and wherein the laser irradiator is configured to irradiate a laser beam of a first power for a first time period and configured to irradiate a laser beam of a second power higher than the first power for a second time period.

### CROSS-REFERENCE TO RELATED APPLICATION

This application claims priority to and the benefit of Korean Patent Application No. 10-2025-0021447, filed on Feb. 19, 2025, in the Korean Intellectual Property Office, the entire disclosure of which is incorporated by reference herein.

### BACKGROUND

### 1. Field

The present disclosure relates to a laser bonding device and a laser bonding method.

### 2. Description of the Related Art

As the information society develops, the demand for display devices for displaying images is increasing in various forms. The display device may be a flat panel display device such as a liquid crystal display, a field emission display, a light emitting display, and/or the like.

The light emitting display device may include an organic light emitting display device including an organic light emitting diode (OLED) element as a light emitting element, and an ultra-small light emitting display device including a micro light emitting diode element (hereinafter referred to as a micro light emitting element) as a light emitting element. Because the micro light emitting diode element is made of an inorganic material, it has the advantage of having a long lifespan due to less deterioration issues compared to an organic light emitting diode (OLED) element.

The manufacturing process of light-emitting display devices requires a process of bonding ultra-small light-emitting diode elements and electronic components to the display panel.

### SUMMARY

Aspects and features of embodiments of the present disclosure are to provide a laser bonding device and a laser bonding method using a conductive bonding pattern that may reduce or minimize heat damage to a backplane substrate during a bonding process.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a laser bonding device includes: a stage configured to support a first substrate; a pressure module configured to fix a plurality of elements on the first substrate; a laser irradiator configured to irradiate a laser beam to a conductive bonding pattern located between the first substrate and the plurality of elements; and a mask located on the first substrate and having openings overlapping the plurality of elements, wherein the plurality of elements includes at least one of a light emitting element, an integrated circuit, or a driving circuit, and wherein the laser irradiator is configured to irradiate a laser beam of a first power for a first time period and configured to irradiate a laser beam of a second power higher than the first power for a second time period.

In one or more embodiments, the conductive bonding pattern includes a polymer resin and conductive nanoparticles dispersed in the polymer resin.

In one or more embodiments, the conductive nanoparticles include a conductive carbon black.

In one or more embodiments, a height of the conductive bonding pattern is 1 μm or less.

In one or more embodiments, the mask includes a light-blocking or a reflective material in an area other than the openings.

In one or more embodiments, the laser irradiator is configured to perform area heating for an area of the first substrate.

In one or more embodiments, the laser irradiator is configured to irradiate the laser beam of the first power for the first time period to have a process temperature of 140° C., and configured to irradiate the laser beam of the second power for the second time period to have the process temperature of 260° C.

In one or more embodiments, a first electrode is on the first substrate, and the conductive bonding pattern is on the first electrode, and wherein the openings of the mask overlap the conductive bonding pattern.

In one or more embodiments, the light emitting element includes a contact electrode on one surface, and a plurality of semiconductor layers on the contact electrode, wherein the contact electrode is on the conductive bonding pattern and electrically connected to the conductive bonding pattern.

In one or more embodiments, a laser bonding method includes: forming a first electrode on a first substrate; forming a conductive bonding pattern on the first electrode; and arranging an element of a plurality of elements on the conductive bonding pattern, the plurality of elements including at least one of a light emitting element, an integrated circuit, or a driving circuit; irradiating the conductive bonding pattern with a laser beam of a first power for a first time period, and irradiating the conductive bonding pattern with a laser beam of a second power higher than the first power for a second time period, and arranging a mask having openings overlapping the plurality of elements on the first substrate before irradiating the laser beam of the second power higher than the first power for the second time period.

In one or more embodiments, the conductive bonding pattern includes a polymer resin and conductive nanoparticles dispersed in the polymer resin.

In one or more embodiments, the conductive nanoparticles include a conductive carbon black.

In one or more embodiments, the forming the conductive bonding pattern includes applying a conductive bonding material to an entire surface of the first substrate covering the first electrode and patterning the conductive bonding pattern using a photolithography process using the mask.

In one or more embodiments, in a pressure member is located between a laser irradiator and the light emitting element and configured to pressurize the light emitting element to 5 MPa while irradiating the laser beam.

In one or more embodiments, the pressure member is configured to pressurize the conductive bonding pattern until a height of each of the conductive bonding pattern is 1 μm or less.

In one or more embodiments, the mask includes a light-blocking or a reflective material in an area other than the openings.

In one or more embodiments, the laser irradiator is configured to perform area heating for an area of the first substrate.

In one or more embodiments, the laser irradiator is configured to irradiate the laser beam of the first power for the first time period to have a process temperature of 140° C., and configured to irradiate the laser beam of the second power for the second time period to have the process temperature of 260° C.

In one or more embodiments, the arranging the element on the conductive bonding pattern includes arranging the light emitting element on a second substrate, wherein a contact electrode of the light emitting element faces the conductive bonding pattern, and wherein, after the laser irradiation is completed, the second substrate is separated and removed from the light emitting element.

In one or more embodiments, an electronic device including a laser bonding device, the laser bonding device includes: a stage configured to support a first substrate; a pressure module configured to fix a plurality of elements on the first substrate; a laser irradiator configured to irradiate a laser beam to a conductive bonding pattern located between the first substrate and the plurality of elements; and a mask located on the first substrate and having openings overlapping the plurality of elements, wherein the plurality of elements includes at least one of a light emitting element, an integrated circuit, or a driving circuit, and wherein the laser irradiator is configured to irradiate a laser beam of a first power for a first time period and configured to irradiate a laser beam of a second power higher than the first power for a second time period.

By using a laser bonding device and a method according to one or more embodiments, heat damage to a backplane substrate may be reduced or minimized during a laser bonding process.

### BRIEF DESCRIPTION OF THE DRAWINGS

FIG. 1 is a perspective view illustrating a display device according to one or more embodiments.

FIG. 2 is a layout drawing illustrating a display device according to one or more embodiments.

FIG. 3 is a cross-sectional view illustrating an example of a cross-section of a display panel corresponding to the line I-I′ of FIG. 2.

FIG. 4 is a block diagram illustrating a display device according to one or more embodiments.

FIG. 5 is an equivalent circuit diagram illustrating a sub-pixel according to one or more embodiments.

FIG. 6 is a layout diagram illustrating pixels of a display area according to one or more embodiments.

FIG. 7 is a cross-sectional view illustrating an example of a cross-section of a display panel corresponding to the line II-II′ of FIG. 6.

FIG. 8 is a cross-sectional view illustrating an example of an area A of FIG. 7 in detail.

FIG. 9 is a layout diagram illustrating pixels of a display area according to one or more embodiments.

FIG. 10 is a cross-sectional view illustrating an example of a cross-section of a display panel corresponding to the line I2-I2′ of FIG. 9.

FIG. 11 is a cross-sectional view illustrating an example of an area B of FIG. 10 in detail.

FIG. 12 is a schematic diagram illustrating a configuration of a laser bonding device according to one or more embodiments.

FIG. 13 is a plan view schematically illustrating a mask according to one or more embodiments.

FIG. 14 is a flowchart illustrating a method for manufacturing a display device using a conductive bonding pattern.

FIG. 15-18 are step-by-step cross-sectional views to illustrate a method for manufacturing a display device according to one or more embodiments.

FIG. 19 is a graph illustrating laser power and laser temperature according to time of a laser bonding device according to one or more embodiments.

FIG. 20 is a cross-sectional view illustrating a method for manufacturing a display device according to one or more embodiments.

FIG. 21 is a diagram illustrating a bonding state according to bonding temperature and bonding pressure in a bonding process by a laser bonding device according to one or more embodiments.

FIGS. 22 and 23 are example drawings illustrating a smart watch including a display device according to one or more embodiments.

FIG. 24 is an exploded perspective view of a smart watch including a display device according to one or more embodiments.

FIG. 25 is an example view of a virtual reality (VR) device including a display device according to one or more embodiments.

FIG. 26 is an example view of a VR device including a display device according to one or more embodiments.

FIG. 27 is an example view illustrating a vehicle instrument cluster and center fascia including display devices according to one or more embodiments.

FIG. 28 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

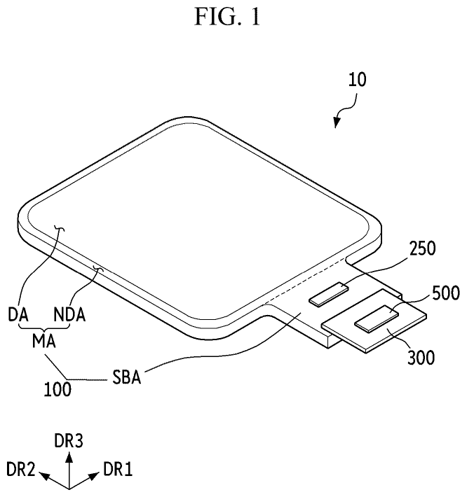

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PC (UMPC), as well as display screens for a variety of products such as televisions, laptops, monitors, billboards, and the internet of things (IOT).

The display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, hereinafter, an ultra-small light emitting diode is described as a light emitting element for convenience of explanation.

The display device 10 includes a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, and/or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits a first color light, a second sub-pixel that emits a second color light, and a third sub-pixel that emits a third color light, but the present disclosure is not limited thereto.

The sub-area SBA may protrude from one side of the main area MA in the second direction DR2. Although FIG. 1 illustrates the sub-area SBA being unfolded, the sub-area SBA may be bent, and in this case, may be arranged on the lower surface of the display panel 100. When the sub-area SBA is bent, it may overlap the main area MA in a third direction DR3, which is the thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit IC and attached to the indication panel 100 using a chip on glass (COG) method, a chip on plastic (COP) method, or an ultrasonic bonding method but is not limited thereto. In one or more embodiments, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit IC and attached to the circuit substrate 300 using a COF method. In one or more embodiments, referring to FIG. 1, the power supply circuit 500 is illustrated as being placed on the circuit board 300 in a COF manner as a packaging method of an integrated circuit (IC), but is not limited thereto, and each integrated circuit IC may be arranged directly on the display panel. Furthermore, in this case, because the size of the integrated circuit IC becomes very small, the integrated circuit IC may be arranged not only in a pad area PA, but also in a display area DA.

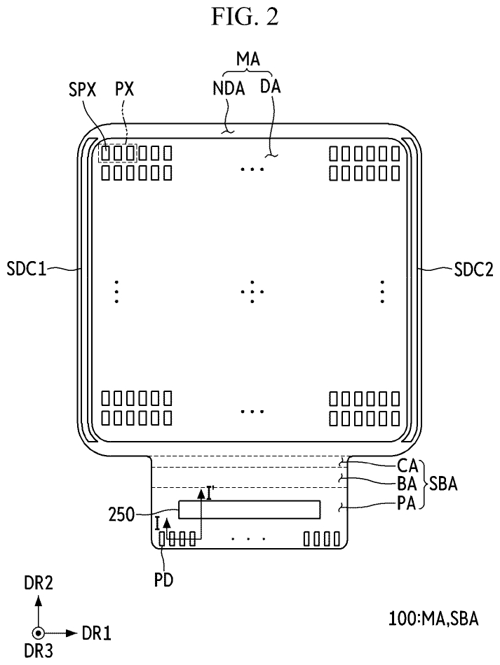

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grays level.

The non-display area NDA may be arranged adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving portion SDC1 and a second scan driving portion SDC2 may be arranged in the non-display area NDA. The first scan driving portion SDC1 is arranged on one side (e.g., the left side) of the display panel 100, and the second scan driving portion SDC2 is arranged on the other side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub area SBA may be less than the length in the first direction DR1 of the main area MA or may be substantially equal to the length in the first direction DR1 of the main area MA. The sub-area SBA may be curved and may be arranged at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where pads PD and a display driving circuit 250 (also referred to as a driving circuit) are arranged. The display driving circuit 250 may be attached to the driving pads of the pad area PA using a conductive bonding pattern CBP. The circuit board 300 may be attached to the pads PD of the pad area PA using the conductive bonding pattern CBP. One side of the pad area PA may be in contact with the bending area BA. In one or more embodiments, the circuit board 300 is attached but is not limited thereto. An integrated circuit IC and a sensor may be directly attached to the pads PD of the pad area PA using the conductive bonding pattern CBP.

The bending area BA is a bent area. When the bending area BA is bent, the pad area PA may be arranged below the connection area CA and below the main area MA. The bending area BA may be arranged between the connection area CA and the pad area PA. One side of the bending area BA may be in contact with the connection area CA, and the other side of the bending area BA may be in contact with the pad area PA.

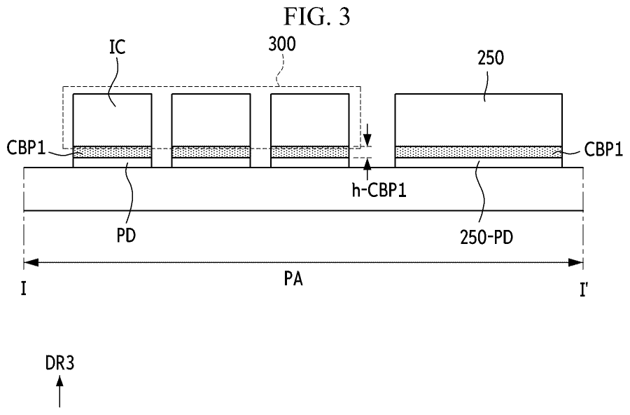

FIG. 3 is a cross-sectional view illustrating an example of a cross-section of a display panel corresponding to the line I-I′ of FIG. 2.

Referring to FIGS. 2 and 3, first pads PD and second pads 250-PD are arranged in the pad area PA.

The first pads PD may be bonded and electrically connected to a circuit board 300 or a direct circuit (IC) through a conductive bonding pattern CBP1. The second pads 250-PD may be bonded and electrically connected to the display driving circuit 250 through a conductive bonding pattern CBP1.

The conductive bonding pattern CBP1 may be referred to as a first conductive bonding pattern CBP1. In one or more embodiments, the conductive bonding pattern CBP is arranged on one surface of the first pad PD and the second pad 250-PD. The first conductive bonding pattern CBP1 may completely overlap one surface of each of the first pad PD and the second pad 250-PD. The first conductive bonding pattern CBP1 may not be arranged between the first pads PD.

Further, the first conductive bonding pattern CBP1 may have the same area as each of the first pads PD and the second pad 250-PD. For example, the first conductive bonding pattern CBP1 may have a rectangular planar shape having a short side having the same length as the short side of the corresponding first pad PD and a long side having the same length as the long side of the corresponding first pad PD. Furthermore, the first conductive bonding pattern CBP1 may have a rectangular planar shape having a short side having the same length as the short side of the corresponding second pad 250-PD and a long side having the same length as the long side of the corresponding second pad 250-PD.

The thickness (height) of the first conductive bonding pattern CBP1, that is, at the interface of the first pad PD corresponding to the first conductive bonding pattern CBP1 and the second pad 250-PD, the interfacial distance h-CBP1 between the first conductive bonding pattern CBP1 and the integrated circuit IC (or sensor) corresponding to the first conductive bonding pattern CBP1 is about 1 μm or less. If the thickness (height) of the first conductive bonding pattern CBP1 is 1 μm or more, a defect may occur in the electrical connection between the first pad PD and the second pad 250-PD and the integrated circuit IC (or sensor).

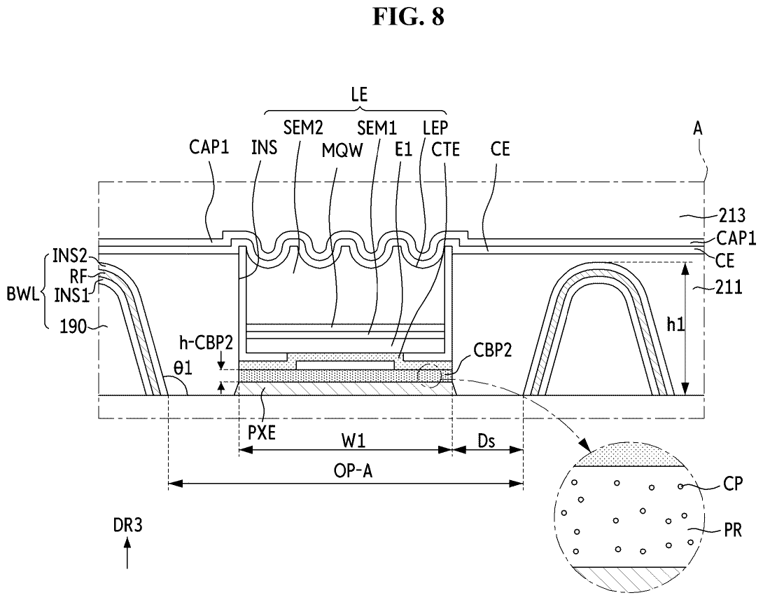

The first conductive bonding pattern CBP1 may be a conductive bonding pattern including conductive nanoparticles CP (e.g., see FIG. 8).

The first conductive bonding pattern CBP1 may include a polymeric resin and conductive nanoparticles CP dispersed in the polymeric resin (e.g., see FIG. 8). The conductive nanoparticle CP is a conductive particle having a particle size of 100 nm or less. The resistance of the conductive nanoparticle CP is 1 ohm or less. In one or more embodiments, the conductive nanoparticle CP may be conductive carbon black but is not limited thereto. In addition to carbon black, the conductive nanoparticle CP may include at least one first materials selected from the group consisting of acetylene black, artificial graphite, natural graphite, copper powder, nickel powder, aluminum powder, indium powder, silver powder, and polyphenylene.

The conductive nanoparticles CP may be dispersed in a polymer resin (e.g., see FIG. 8). The polymer resin may be a photosensitive resin PR (e.g., see FIG. 8) but is not limited thereto. The photosensitive resin PR may be an insulating material. As the photosensitive resin PR, the photosensitive resin may be an acrylic resin or a polyimide resin. The first conductive bonding pattern CBP1 may be patterned by a photolithography process. Therefore, the first conductive bonding pattern CBP1 may be applied to high-brightness display panels as well as fine patterning.

The first conductive bonding pattern CBP1 may be melted at less than 200 degrees, such as at 140 degrees, and used as an adhesive.

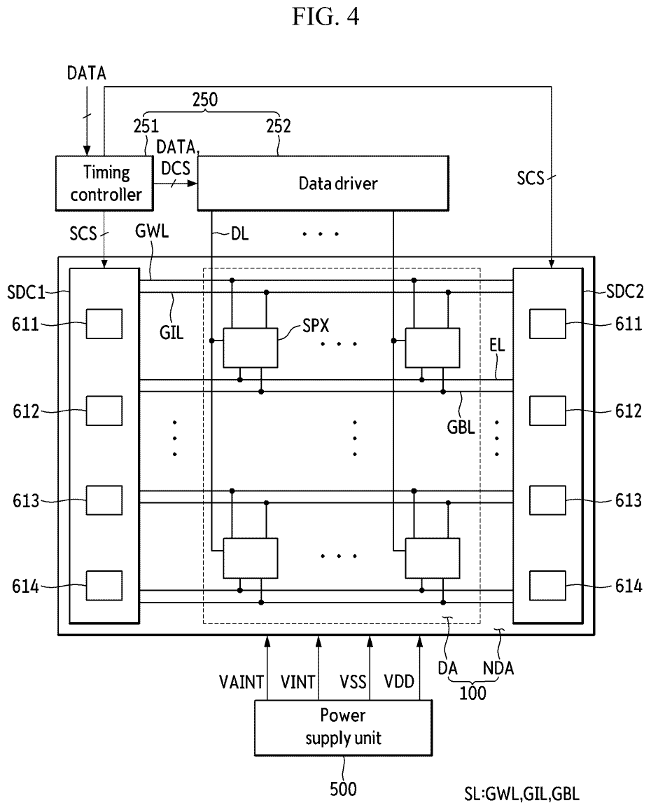

FIG. 4 is a block diagram illustrating a display device according to one or more embodiments.

Referring to FIG. 4, the display area DA includes a plurality of pixels PX (each of the pixels PX including a plurality of sub-pixel SPX), a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along rows and columns of a matrix form along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of initialization scan lines GIL, and a plurality of bias scan lines GBL. In one or more embodiments, the plurality of scan lines SL may also include a plurality of control scan lines GCL.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. In one or more embodiments, each of the plurality of sub-pixels SPX may also be connected to a control scan line GCL from among the plurality of control scan lines GCL. Each of the plurality of sub-pixels SPX may be supplied with a data voltage of the data line DL according to the write scan signal of the write scan line GWL and may emit light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 includes a timing control circuit (e.g., a timing controller) 251 and a data driving circuit (e.g., a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 251 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., a power supply unit) 500 may generate a plurality of panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

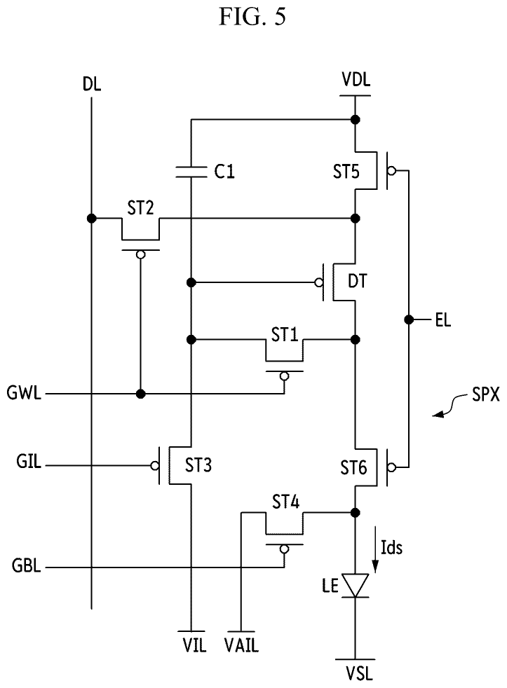

FIG. 5 is an equivalent circuit diagram illustrating a sub-pixel according to one or more embodiments.

Referring to FIG. 5, a sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to one or more embodiments includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as “driving current”) flowing between the first electrode and the second electrode according to a data voltage applied to a gate electrode of the driving transistor DT.

The light emitting element LE may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between the gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 5, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET and they may be turned on when a scan signal of a gate low voltage and an emission control signal are applied to the initialization scan line GIL, the write scan line GWL, the bias scan line GBL, and the emission line EL, respectively. One electrode of the third transistor ST3 may be connected to the first initialization voltage line VIL to which the third power supply voltage (VINT of FIG. 3) is applied, and one electrode of the fourth transistor ST4 may be connected to the second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, because the first transistor ST1 and the third transistor ST3 are formed as n-type MOSFET, the first transistor ST1 may be turned on when a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal of a gate low voltage are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and a light emission control signal are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and a light emission control signal are applied.

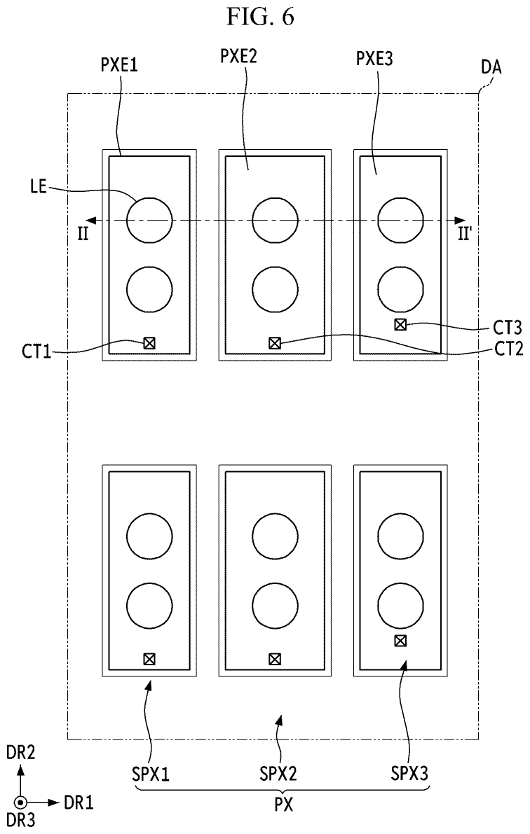

FIG. 6 is a layout diagram illustrating pixels of a display area according to one or more embodiments.

Referring to FIG. 6, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels, the three sub-pixels may be the first sub-pixel SPX1, the second sub-pixel SPX2, and the third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a red wavelength band, the second color light may be light in a green wavelength band, and the third color light may be light in a blue wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1 and a plurality of light emitting elements LE. The second sub-pixel SPX2 includes a second pixel electrode PXE2 and a plurality of light emitting elements LE. The third sub-pixel SPX3 includes a third pixel electrode PXE3 and a plurality of light emitting elements LE.

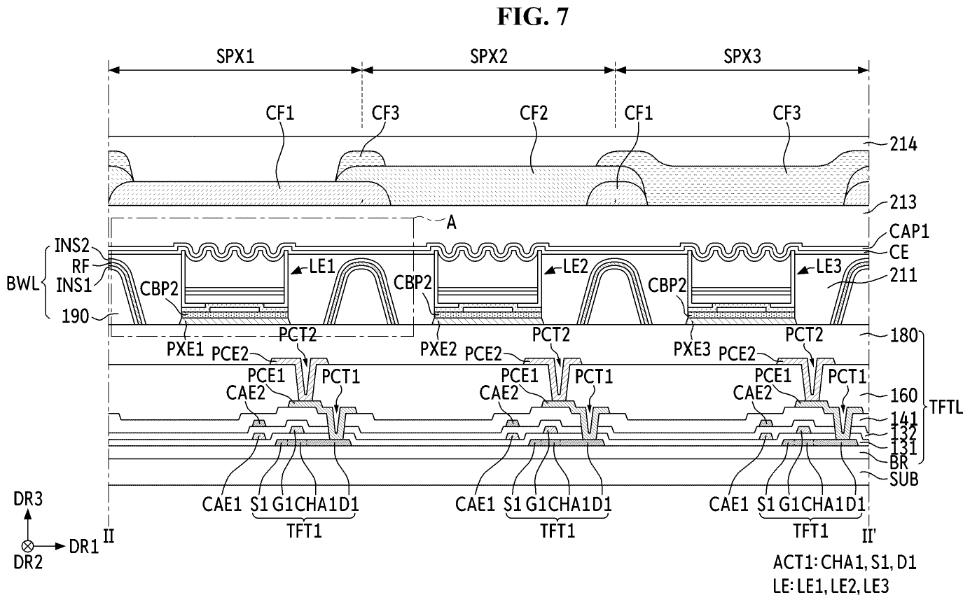

In one or more embodiments, the light emitting element LE (e.g., see LE1 of FIG. 7) of the first sub-pixel SPX1 may emit light of a first color, the light emitting element LE (e.g., see LE2 of FIG. 7) of the second sub-pixel SPX2 may emit light of a second color, and the light emitting element LE (e.g., see LE3 of FIG. 7) of the third sub-pixel SPX3 may emit light of a third color.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light-emitting efficiency of the light emitting element LE included in each sub-pixel SPX. For example, the area of the sub-pixel may be larger as the light conversion efficiency decreases.

For example, as shown in FIG. 5, when the light emission efficiency of the light emitting element LE of the second sub-pixel SPX2 is lower than the light emission efficiency of the light emitting element LE of the first sub-pixel SPX1 and the light emitting element LE of the third sub-pixel SPX3, the area of the second pixel electrode PXE2 may be larger than the area of the first pixel electrode PXE1 and larger than the area of the third pixel electrode PXE3.

Each of the pixel electrodes PXE1, PXE2, and PXE3 may be electrically connected to at least one transistor through the pixel connection hole CT1, CT2, and CT3, respectively. For example, each of the pixel electrodes PXE1, PXE2, and PXE3 may be electrically connected to the first electrode of the fourth transistor (ST4 in FIG. 4) and the second electrode of the sixth transistor (ST6 in FIG. 4) of the corresponding sub-pixel.

In one or more embodiments, the plurality of light emitting elements LE may be arranged on each of the pixel electrodes PXE1, PXE2, and PXE3. The same number of light emitting elements LE may be arranged on each of the pixel electrodes PXE1, PXE2, and PXE3. For example, two light emitting elements LE may be arranged on each of the pixel electrodes PXE1, PXE2, and PXE3. In one or more embodiments, the plurality of light emitting elements LE may emit light of a third color, that is, light in a blue wavelength band, but the present disclosure is not limited thereto.

Each of the plurality of light emitting elements LE may have a circular planar shape, but the present disclosure is not limited thereto. For example, each of the plurality of light emitting elements LE may have a rectangular planar shape.

FIG. 7 is a cross-sectional view illustrating an example of a cross-section of a display panel corresponding to the line II-II′ of FIG. 6. FIG. 8 is a cross-sectional view illustrating an example of an area A of FIG. 7 in detail.

Referring to FIG. 7-8, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film that protects the transistors of a thin-film transistor layer TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin film transistor TFT1 and on the barrier film BR.

A first gate metal layer may be arranged on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged spaced (or apart) from each other in FIG. 6, the first gate electrode G1 and the first capacitor electrode CAE1 may be connected to each other.

A second gate insulating film 132 may be arranged on the first gate electrode G1 and the first capacitor electrode CAE1 of the thin film transistor TFT1 and on the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a suitable dielectric constant (e.g., a predetermined dielectric constant), the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be arranged on the first source connection electrode PCE1 and on the first interlayer insulating film 141 to planarize a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be arranged on the second source connection electrode PCE2 and on the first planarization organic film 160.

The barrier film BR, the first gate insulating film 131, the second gate insulating film 132, and the interlayer insulating film 141 may be formed of an inorganic film, for example, silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed of an organic film such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, and PXE3, a first conductive bonding pattern CBP1, light emitting elements LE, a common electrode CE, and an organic partition wall BWL.

A pixel electrode layer and a first organic layer 190 may be arranged on the second planarization organic film 180. The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a connection hole (CT1/CT2/CT3 in FIG. 6) penetrating the second planarization organic film 180. Each of the pixel electrodes PXE1, PXE2, and PXE3 may be connected to a first source area S1 or a first drain area D1 of a thin film transistor TFT1 through a first source connection electrode PCE1 and a second source connection electrode PCE2. Therefore, a voltage controlled by the thin film transistor TFT1 may be applied to each of the pixel electrodes PXE1, PXE2, and PXE3.

The pixel electrodes PXE1, PXE2, and PXE3 may be formed as a single layer or multiple layers made of molybdenum (Mo), aluminum (Al), chromium (Cr), gold (Au), titanium (Ti), nickel (Ni), neodymium (Nd), and/or copper (Cu), and/or an alloy thereof. For example, the pixel electrode layer may be made of copper (Cu) having a low surface resistance to lower the resistance of each of the pixel electrodes PXE1, PXE2, and PXE3. Furthermore, the pixel electrodes PXE1, PXE2, and PXE3 may include a first layer made of one or an alloy of molybdenum (Mo), aluminum (Al), chromium (Cr), gold (Au), titanium (Ti), nickel (Ni), neodymium (Nd), and/or copper (Cu) at the bottom when the pixel electrodes PXE1, PXE2, and PXE3 are formed in multiple layers, and a second layer made of a metal material having a high reflectivity, such as aluminum (Al), on the first layer.

The second conductive bonding pattern CBP2 may be arranged on one surface of each of the first pixel electrode PXE1, the second pixel electrode PXE2, and the third pixel electrode PXE3. In one or more embodiments, the second conductive bonding pattern CBP2 may completely overlap one surface of each of the first pixel electrode PXE1, the second pixel electrode PXE2, and the third pixel electrode PXE3. Further, the second conductive bonding pattern CBP2 may have the same area as the corresponding pixel electrodes PXE1, PXE2, and PXE3. For example, the second conductive bonding pattern CBP2 may have a rectangular planar shape having a short side having the same length as the short side of the corresponding pixel electrodes PXE1, PXE2, and PXE3 and a long side having the same length as the long side of the corresponding pixel electrodes PXE1, PXE2, and PXE3.

The thickness (height) of the second conductive bonding pattern CBP2, that is, the distance h-CBP2 between the interface between the second conductive bonding pattern CBP2 and the corresponding pixel electrode PXE1, PXE2, and PXE3 and the interface between the second conductive bonding pattern CBP2 and the contact electrode CTE of the corresponding light emitting element LE, is about 1 μm or less.

The light emitting elements LE may be bonded and electrically connected to the corresponding pixel electrodes PXE1, PXE2, and PXE3 by the second conductive bonding pattern CBP2.

The second bonding adhesive pattern CBP2 may be a conductive bonding pattern including a conductive nanoparticle CP. The second bonding adhesive pattern CBP2 may include a polymer resin (e.g., a photosensitive resin PR) and conductive nanoparticles CP dispersed in the polymer resin (e.g., a photosensitive resin PR). The conductive nanoparticles CP are conductive particles having a particle size of 100 nm or less. The resistance of the conductive nanoparticles CP is 1 ohm or less.

The conductive nanoparticles CP may be conductive carbon black but is not limited thereto. In addition to carbon black, the conductive nanoparticles CP may include at least one of the first materials selected from the group consisting of acetylene black, artificial graphite, natural graphite, copper powder, nickel powder, aluminum powder, indium powder, silver powder, and polyphenylene.

The second conductive bonding pattern CBP2 may be melted at less than 200 degrees, for example, at 140 degrees, to bond the light emitting elements LE onto the corresponding pixel electrodes PXE1, PXE2, and PXE3.

The second conductive bonding pattern CBP2 may be the same material as the first conductive bonding pattern (CBP1 in FIG. 3).

The second conductive bonding pattern CBP2 may further include a photosensitive resin. The photosensitive resin may be an acrylic-based resin, a polyimide-based resin, and/or the like. The second conductive bonding pattern CBP2 may be patterned using a photolithography process. Therefore, the second conductive bonding pattern CBP2 may also be finely patterned and may be applied to a high-brightness display panel.

The organic partition wall BWL may be formed on the second planarization organic film 180 with a first inclination angle θ1 and a first height h1. The bottom of the organic partition wall BWL may be positioned lower than the bottom of the light emitting element LE.

When the upper end of the organic partition wall BWL is formed lower than the light emitting element LE, the light emitting element LE may be easily transferred during the light emitting element LE transfer process.

The first inclination angle θ1 may be about 120 degrees to 135 degrees. The first height h1 may be about 5 μm to 8 μm but is not limited thereto.

The organic partition wall BWL may define a first opening area OP-A. The first opening area OP-A may expose the second planarization organic film 180 as a lower layer and the pixel electrodes PXE1, PXE2, and PXE3. The area exposed by the first opening area OP-A may be larger than the area of the light emitting element LE.

The organic partition wall BWL may include a first organic layer 190 defining the shape of the partition wall, a first protective film INS1 covering the first organic layer 190, a reflective film RF, and a second protective film INS2.

The upper end of the first organic layer 190 may be higher than the active layer MQW of the light emitting element LE and may be lower than the top of the light emitting element LE.

The first organic layer 190 may be formed of an organic material such as an acrylic resin, an epoxy resin, a phenolic resin, a polyamide resin, a polyimide resin, and/or the like.

The first protective film INS1 is arranged outside the first organic layer 190. The first protective film INS1 may cover the entire first organic layer 190.

The reflective film RF is arranged outside the first protective film INS1.

The second protective film INS2 is arranged on top of the reflective film RF. The reflective film RF is surrounded by the first protective film INS1 and the second protective film INS2. For example, the reflective film RF may be interposed between the first protective film INS1 and the second protective film INS2.

The reflective film RF may be a closed loop shape that surrounds the side of the light emitting element LE and is spaced (e.g., spaced apart) from the light emitting element LE on a plane (e.g., in a plan view). The upper end of the reflective film RF may be positioned higher than the active layer MQW of the light emitting element LE. The lower end of the reflective film RF may be arranged lower than the light emitting element LE. The reflective film RF may include a metal material with high reflectivity, such as aluminum (Al).

The reflective film RF may reflect light traveling in a lateral direction from the light-emitting element LE and emit light to the top surface of the light emitting element LE. Therefore, because the loss of light from the light emitting element LE may be reduced, the light efficiency of the light emitting element LE may be increased.

The front light emission efficiency may increase as the slope θ1 of the reflective film RF increases, but the width of the first organic layer 190 may increase as the slope θ1 of the reflective film RF increases. Therefore, it may be preferable that the slope θ1 of the reflective film RF be about 120° to 130°.

The first protective film INS1 and the second protective film INS2 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A plurality of light emitting elements LE may be arranged on the pixel electrodes PXE1, PXE2, and PXE3. In FIGS. 7 and 8, each of the plurality of light emitting elements LE is illustrated as a vertical type micro LED extending in the third direction DR3. The vertical type micro LED refers to an LED having a structure in which a first semiconductor layer SEM1, an active layer MQW, and a second semiconductor layer SEM2 are sequentially arranged along the third direction DR3, which is a vertical direction.

The light emitting element LE may include substantially vertical side surfaces as illustrated in FIG. 8. For example, the light emitting element LE may be patterned through vertical etching and may have a rectangular or square cross-sectional shape in which the width of the top surface and the width of the bottom surface are substantially the same. The shape of the light emitting element LE may vary depending on the embodiments. For example, the light emitting element LE may have a reverse taper cross-sectional shape. For example, the light emitting element LE may have a reverse trapezoidal cross-sectional shape in which the width of the top surface is wider than the width of the bottom surface.

Each of the plurality of light emitting elements LE may be formed of an inorganic material such as gallium nitride (GaN). Each of the plurality of light emitting elements LE may have a length in the first direction DR1, a length in the second direction DR2, and a length in the third direction DR3, respectively, of several to several hundred μm. For example, each of the plurality of light emitting elements LE may have a length in the first direction DR1, a length in the second direction DR2, and a length in the third direction DR3 of approximately 6 μm to 10 μm or less.

Each of the plurality of light emitting elements LE may be formed by growing on a semiconductor substrate such as a silicon substrate or a sapphire substrate. The plurality of light emitting elements LE may be transferred directly from the semiconductor substrate onto the pixel electrodes PXE1, PXE2, and PXE3 of the display panel 100. Alternatively, the plurality of light emitting elements LE may be transferred onto the pixel electrodes PXE1, PXE2, and PXE3 of the display panel 100 by an electrostatic method using an electrostatic head or a stamp method using an elastic polymer material such as PDMS or silicon as a transfer substrate.

The light emitting element LE may include a conductive layer E1, a first semiconductor layer SEM1, an active layer MQW, a second semiconductor layer SEM2, a contact electrode CTE, and a protective film INS.

The conductive layer E1 may be arranged on the bottom surface of the first semiconductor layer SEM1. In FIG. 7, the conductive layer E1 is illustrated covering the entire underside of the first semiconductor layer SEM1, but the present disclosure is not limited thereto. For example, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu).

The first semiconductor layer SEM1 may be arranged on the conductive layer E1. The first semiconductor layer SEM1 may be formed of a semiconductor material layer doped with a first-conductivity dopant such as magnesium (Mg), zinc (Zn), calcium (Ca), strontium (Sr), barium (Ba), and/or the like, such as gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) and/or aluminum gallium nitride (AlGaN), but the present disclosure is not limited thereto.

Alternatively, the active layer MQW may have a structure in which semiconductor materials having a high band gap energy and semiconductor materials having a low band gap energy are alternately stacked with each other, may include other Group III to Group V semiconductor materials according to the wavelength range of emitted light.

In one or more embodiments, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third color light (e.g., light in the blue wavelength band) may be approximately 10 wt% to 20 wt%.

The second semiconductor layer SEM2 may be arranged on the active layer MQW. The second semiconductor layer SEM2 may be a semiconductor material layer doped with a second conductive dopant such as silicon (Si), germanium (Ge), tin (Sn), and/or the like, for example gallium nitride (GaN).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

A light extraction patterns LEP may be formed on the top surface of the semiconductor stack STC (SEM1, MQW, SEM2). For example, the light extraction patterns LEP may be formed on the top surface of the second semiconductor layer SEM2.

The light extraction patterns LEP may be patterns for increasing the efficiency of light emitted from the top surface of the light emitting element LE. The light extraction patterns LEP may be concave patterns formed in a hemisphere or a semi-ellipse. The light extraction patterns LEP may be concave patterns having a cross-sectional shape of a semicircle or a semi-ellipse.

The protective film INS may be a film for protecting the bottom surface and the side surface (e.g., an outer peripheral surface) of the light emitting element LE. The protective film INS may be arranged on the bottom surface and the side surface of the conductive layer E1 and the side surface of the semiconductor stack STC (SEM1, MQW, SEM2). Specifically, the protective film INS may be arranged on the bottom surface and side surface of the conductive layer E1, the side surface of the first semiconductor layer SEM1, the side surface of the active layer MQW, and the side surface of the second semiconductor layer SEM2. The protective film INS may be formed of an inorganic film, such as silicon nitride (SiNₓ), silicon oxide nitride (SiON), silicon oxide (SiOₓ), titanium oxide (TiOₓ), and/or aluminum oxide (AlOₓ).

The contact electrode CTE may be arranged on the protective film INS. The contact electrode CTE may be arranged between the pixel electrodes PXE1, PXE2, and PXE3 and the protective film INS. The contact electrode CTE may be in contact with the pixel electrodes PXE1, PXE2, and PXE3.

The contact electrode CTE may be connected to the conductive layer E1 that is exposed and not covered by the protective film INS.

The contact electrode CTE may include molybdenum (Mo), aluminum (Al), chromium (Cr), gold (Au), titanium (Ti), nickel (Ni), neodymium (Nd), and/or copper (Cu). Specifically, the plurality of contact electrodes CTE may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The distance Ds between the light emitting element LE and the organic partition wall BWL may be smaller than the width W1 of the light emitting element LE.

The second organic layer 211 may be arranged to cover the side surfaces of the plurality of light emitting elements LE.

The second organic layer 211 is a layer for flattening the steps caused by the plurality of light emitting elements LE. The height of the second organic layer 211 may be arranged to cover most of the side surfaces of each of the plurality of light emitting elements LE, but in another embodiment, the second organic layer 211 may be arranged to cover the side surfaces of each of the plurality of light emitting elements LE by a plurality of organic films.

The second organic layer 211 may be formed of an organic film such as an acrylic resin, an epoxy resin, a phenolic resin, a polyamide resin, and/or a polyimide resin.

The common electrode CE may be arranged on the top surface of each of the plurality of light emitting elements LE and the top surface of the second organic layer 211.

The common electrode CE may be a common layer formed commonly on the first sub-pixel SPX1, the second sub-pixel SPX2, and the third sub-pixel SPX3. The common electrode CE may be made of a transparent conductive material (TCO) such as indium tin oxide (ITO) and/or indium zinc oxide (IZO) that may transmit light.

The pixel electrodes PXE1, PXE2, and PXE3 may be referred to as an anode electrode or a first electrode, and the common electrode CE may be referred to as a cathode electrode or a second electrode.

A first capping layer CAP1 may be arranged on the common electrode CE. The first capping layer CAP1 may serve to encapsulate the underlying component.

The first capping layer CAP1 may be formed of an inorganic film, such as silicon nitride (SiNₓ), silicon oxide nitride (SiON), silicon oxide (SiOₓ), titanium oxide (TiOₓ), and/or aluminum oxide (AlOₓ).

A third organic layer 213 may be arranged on the first capping layer CAP1. A plurality of color filters CF1, CF2, and CF3 may be arranged on the third organic layer 213. The plurality of color filters CF1, CF2, and CF3 may include first color filters CF1, second color filters CF2, and third color filters CF3.

The first color filter CF1 arranged in the first sub-pixel SPX1 may transmit the first color light (e.g., light in the red wavelength band). Therefore, the first sub-pixel SPX1 may emit the first color light (e.g., light in the red wavelength band).

The second color filter CF2 arranged in the second sub-pixel SPX2 may transmit the second color light (e.g., light in the green wavelength band). Therefore, the second sub-pixel SPX2 may emit the second color light (e.g., light in the green wavelength band).

The third color filter CF3 arranged in the third sub-pixel SPX3 may transmit the third color light (e.g., light of a blue wavelength band). Therefore, the third sub-pixel SPX3 may emit the third color light (light of a blue wavelength band).

The first color filter CF1, the second color filter CF2, and the third color filter CF3 overlapping in the third direction DR3 may overlap the organic partition wall BWL in the third direction DR3.

A fourth organic layer 214 for planarization may be arranged on the plurality of color filters CF1, CF2, and CF3.

The third organic layer 213 and the fourth organic layer 214 may be formed from an acrylic resin, an epoxy resin, a phenolic resin, a polyamide resin, a polyimide resin, and/or the like.

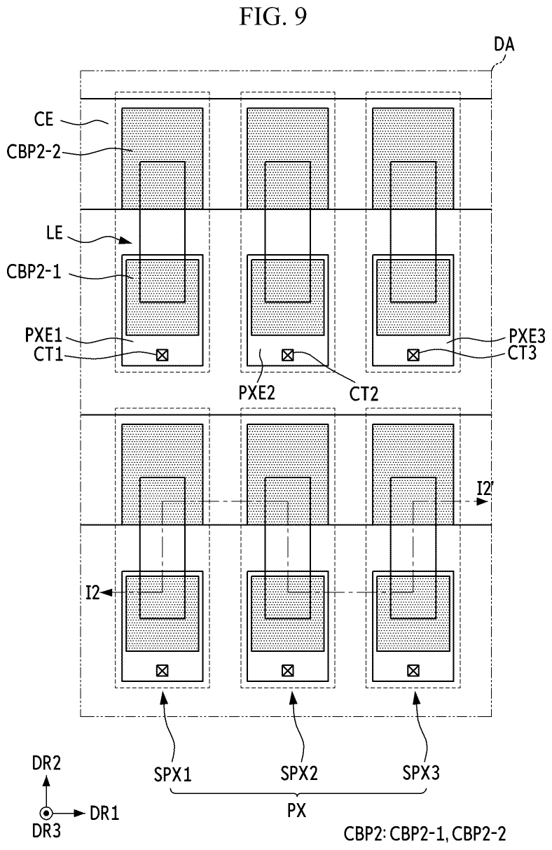

FIG. 9 is a layout diagram illustrating pixels of a display area according to one or more embodiments.

The embodiment of FIG. 9 differs from the embodiment of FIG. 6 in that the light emitting elements LE are arranged on the pixel electrodes PXE1, PXE2, and PXE3 and the common electrode CE in each of the first sub-pixel SPX1, the second sub-pixel SPX2, and the third sub-pixel SPX3. In FIG. 9, descriptions that overlap with the embodiment of FIG. 6 will be omitted, and differences from the embodiment of FIG. 6 will be mainly described.

Referring to FIG. 9, the pixel electrodes PXE1, PXE2, and PXE3 and the common electrode CE in each of the first sub-pixel SPX1, the second sub-pixel SPX2, and the third sub-pixel SPX3 may be arranged along the second direction DR2. Each of the pixel electrodes PXE1, PXE2, and PXE3 and the common electrodes CE may have a rectangular planar shape, but the present disclosure is not limited thereto.

The common electrode CE may be connected to a second power supply line VSL to which a second driving voltage VSS is applied. Therefore, the second driving voltage VSS may be applied to each of the common electrodes CE.

In each of the first sub-pixel SPX1, the second sub-pixel SPX2, and the third sub-pixel SPX3 light emitting element LE may be arranged on the pixel electrodes PXE1, PXE2, and PXE3 and the common electrode CE, so that the length of the light emitting element LE in the second direction DR2 may be longer than the length in the first direction DR1.

The second conductive bonding pattern CBP2 may include a 2-1 conductive bonding pattern CBP2-1 and a 2-2 conductive bonding pattern CBP2-2.

The 2-1 conductive bonding pattern CBP2-1 is arranged on the pixel electrodes PXE1, PXE2, and PXE3 of each sub-pixel SPX1, SPX2, and SPX3, and may have an area smaller than one side of the pixel electrodes PXE1, PXE2, and PXE3. The 2-1 conductive bonding pattern CBP2-1 may have a rectangular planar shape having a short side having the same length as the short side of the corresponding pixel electrodes PXE1, PXE2, and PXE3 and a long side having the same length as the long side of the corresponding pixel electrodes PXE1, PXE2, and PXE3.

The 2-2 conductive bonding pattern CBP2-2 is arranged on the common electrode CE of each sub-pixel SPX1, SPX2, and SPX3, and may have an area smaller than one side of the common electrode CE. The 2-2 conductive bonding pattern CBP2-2 may have a rectangular planar shape having a long side in the first direction DR1 and a short side in the second direction DR2 or having a long side in the second direction DR2 and a short side in the first direction DR1, similar to the 2-1 conductive bonding pattern CBP2-1.

The 2-1 conductive bonding pattern CBP2-1 and the 2-2 conductive bonding pattern CBP2-2 of each sub-pixel SPX1, SPX2, and SPX3 may be formed with the same area.

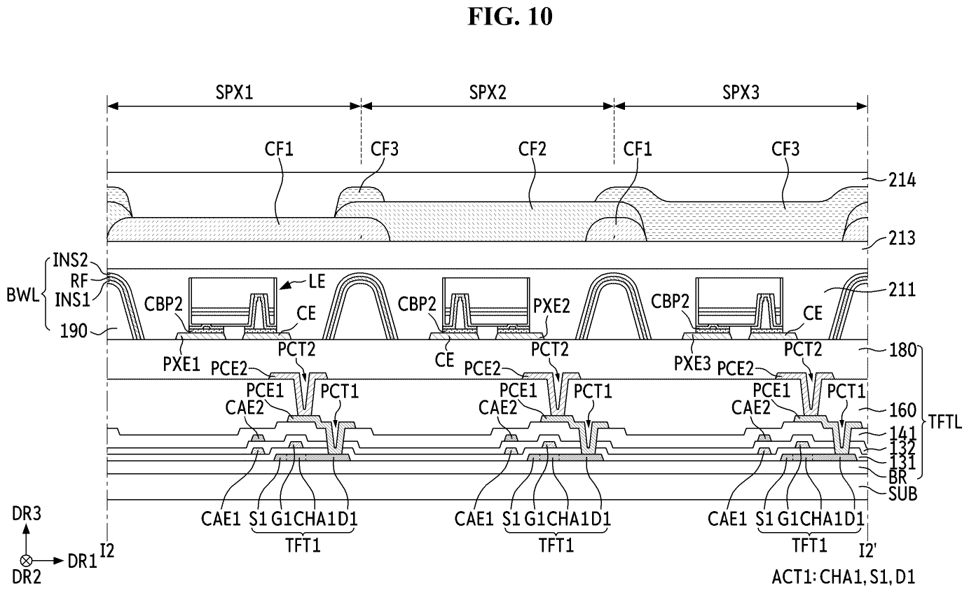

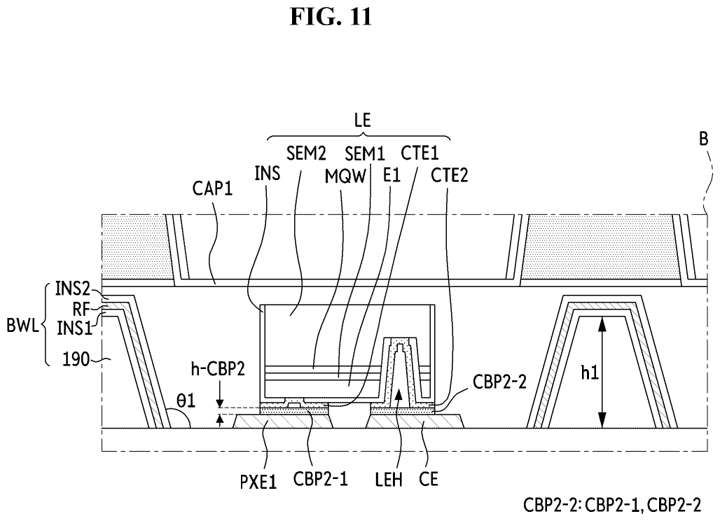

FIG. 10 is a cross-sectional view illustrating an example of a cross-section of a display panel corresponding to the line I2-I2′ of FIG. 9. FIG. 11 is a cross-sectional view illustrating an example of an area B of FIG. 10 in detail.

The embodiments of FIGS. 10 and 11 differ from the embodiments of FIGS. 7 and 8 in that the light emitting element LE is a flip-type micro LED. In FIGS. 10 and 11, descriptions that overlap with the embodiments of FIGS. 7 and 8 will be omitted, and differences from the embodiments of FIGS. 7 and 8 will be mainly described.

Referring to FIGS. 10 and 11, a pixel electrode layer including pixel electrodes PXE1, PXE2, and PXE3 and a common electrode CE may be arranged on a second planarization organic film 180.

The light emitting element LE may be a flip-type micro LED. The flip-type micro LED refers to an LED in which contact electrodes CTE1 and CTE2 are formed on one surface (e.g., the bottom surface) of the light emitting element LE.

In FIG. 11, a protective film INS is illustrated arranged on bottom surface and the side surface of the conductive layer E1 and the side surfaces of the first semiconductor layer SEM1, the side surfaces of the active layer MQW, and the side surfaces of the second semiconductor layer SEM2, but the present disclosure is not limited thereto. For example, the protective film INS may be arranged on the side surfaces of the first semiconductor layer SEM1, the side surfaces of the active layer MQW, and the side surfaces of the second semiconductor layer SEM2 of the semiconductor stack STC.

A plurality of light emitting elements LE may be arranged on the pixel electrodes PXE1, PXE2, and PXE3 and the common electrode CE.

A first contact electrode CTE1 may be arranged on the pixel electrodes PXE1, PXE2, and PXE3, and a second contact electrode CTE2 may be arranged on the common electrode CE.

A hole LEH may be formed to expose a second semiconductor layer SEM2 by penetrating the conductive layer E1, the first semiconductor layer SEM1, and the active layer MQW of the light emitting element LE. The hole LEH may have a circular planar shape, but the present disclosure is not limited thereto. For example, the hole LEH may have a polygonal planar shape, such as an oval or a square.

Further, the protective film INS may be arranged on the sidewall of the conductive layer E1 exposed in the hole LEH, the sidewall of the first semiconductor layer SEM1, the sidewall of the active layer MQW, and the sidewall of the second semiconductor layer SEM2. The protective film INS may not cover the second semiconductor layer SEM2 in the hole LEH.

The first contact electrode CTE1 may be arranged on one surface of the conductive layer E1. Therefore, the first contact electrode CTE1 may be electrically connected to the conductive layer E1. For example, the first contact electrode CTE1 may be arranged on the protective film INS. The first contact electrode CTE1 may be arranged between the pixel electrodes PXE1, PXE2, and PXE3 and the protective film INS. The first contact electrode CTE1 may be connected to the conductive layer E1 that is exposed and not covered by the protective film INS.

The second contact electrode CTE2 may be arranged on one surface of the conductive layer E1 to be spaced (e.g., spaced apart) from the first contact electrode CTE1. The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

The 2-1 conductive bonding pattern CBP2-1 may be arranged on one surface of each of the first pixel electrode PXE1, the second pixel electrode PXE2, and the third pixel electrode PXE3. In one or more embodiments, the 2-1 conductive bonding pattern CBP2-1 may completely overlap one side of each of the first pixel electrode PXE1, the second pixel electrode PXE2, and the third pixel electrode PXE3. Further, the first contact electrode CTE1 of the light emitting element LE may be arranged on the 2-1 conductive bonding pattern CBP2-1. The 2-1 conductive bonding pattern CBP2-1 may be electrically connected to the first contact electrode CTE1 of the light emitting element LE.

The 2-2 conductive bonding pattern CBP2-2 may be arranged on a portion of one side of the common electrode CE. Further, the second contact electrode CTE2 of the light emitting element LE may be arranged on the 2-2 conductive bonding pattern CBP2-2. The 2-2 conductive bonding pattern CBP2-2 may be electrically connected to the second contact electrode CTE2 of the light emitting element LE.

The thickness (height) of the second conductive bonding pattern CBP2, that is, the distance h-CBP2 between the interface between the second conductive bonding pattern CBP2 and the corresponding pixel electrode PXE1, PXE2, and PXE3 (or the common electrode CE) and the interface between the second conductive bonding pattern CBP2 and the corresponding contact electrode CTE1 and CTE2 of the light emitting element LE, is about 1 μm or less.

The first contact electrode CTE1 of the light emitting element LE may be bonded and electrically connected to the corresponding pixel electrodes PXE1, PXE2, and PXE3 by the 2-1 conductive bonding pattern CBP2-1. The second contact electrode CTE2 of the light emitting elements LE may be bonded and electrically connected to the corresponding common electrode CE by the 2-2 conductive bonding pattern CBP2-2.

The organic partition wall BWL may be formed on the second planarization organic film 180 with a first inclination angle θ1 and a first height h1.

The first inclination angle θ1 may be 120 degrees or more. Preferably, the first inclination angle θ1 may be about 120 degrees to 135 degrees. The first height h1 may be about 5 μm to 6 μm.

The organic partition wall BWL may have a first opening area OP-A defined therein (e.g., see FIG. 8). The first opening area OP-A may expose the second planarization organic film 180, which is a lower layer, pixel electrodes PXE1, PXE2, and PXE3, and the common electrode CE. The area exposed by the first opening area OP-A may be larger than the area of the light emitting element LE.

The organic partition wall BWL may include a first organic layer 190 defining the shape of the partition wall, a first protective film INS1 covering the first organic layer 190, a reflective film RF, and a second protective film INS2.

The reflective film RF is arranged outside the first protective film INS1. The second protective film INS2 is arranged on top of the reflective film RF. The reflective film RF is surrounded by the first protective film INS1 and the second protective film INS2.

The reflective film RF may be a closed loop shape that is around (e.g., that surrounds) the side of the light emitting element LE and is spaced (e.g., spaced apart) from the light emitting element LE on a plane (e.g., in a plan view). The upper end of the reflective film RF may be positioned higher than the active layer MQW of the light emitting element LE. The lower end of the reflective film RF may be positioned lower than the light emitting element LE. The reflective film RF may include a metal material having a high reflectivity, such as aluminum (Al).

The vertical distance (height) from the uppermost end of the reflective film RF to the lowermost end of the reflective film RF is 80% to 120% of the height of the light emitting element LE. When the reflective film RF is formed higher than the height of the light emitting element LE, there is an advantage in terms of light emission efficiency, and when the reflective film RF is formed lower than the height of the light emitting element LE, the light emitting element LE may be easily transferred.

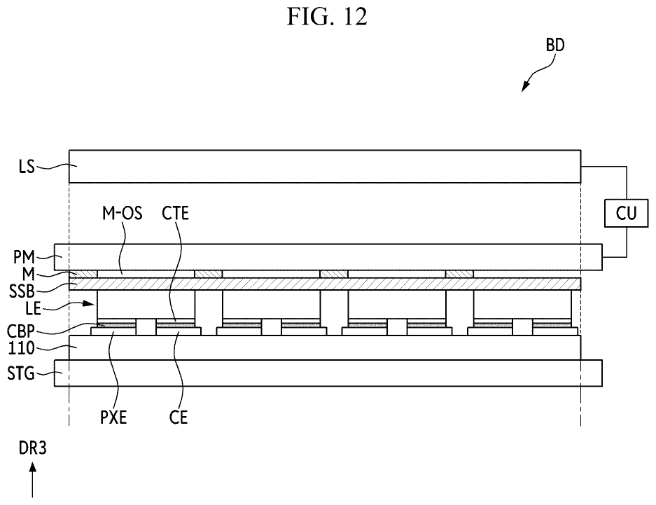

FIG. 12 is a schematic diagram illustrating a configuration of a laser bonding device according to one or more embodiments. FIG. 13 is a plan view schematically illustrating a mask according to one or more embodiments.

The laser bonding device BD is capable of bonding two or more bonding objects together using a laser beam. The bonding objects may be a substrate, a film, a display panel, a touch panel, and/or a semiconductor device such as a printed circuit board (PCB), a flexible circuit board, and/or a light emitting device. For example, according to one or more embodiments, as shown in FIG. 12, the first bonding object may be a backplane substrate 110 and the second bonding object may be a light emitting element LE but is not limited thereto. For example, as described with reference to FIG. 3, the second bonding object may be a direct circuit (IC of FIG. 3) or a display driving circuit (250 of FIG. 3) instead of the light emitting element LE.

Referring to FIG. 12, the laser bonding device BD may bond the light emitting element LE to the backplane substrate 110 by irradiating a laser beam.

The laser bonding device BD may include a stage STG, a pressure member PM that applies pressure in a downward direction, a mask M, and a laser irradiator LS that may irradiate a laser beam.

The stage STG has a top surface parallel to a plane defined by a first direction DR1 and a second direction DR2 that are perpendicular to each other. A bonding target, e.g., a backplane substrate 110, is arranged on the top surface of the stage STG.

The stage STG and the laser bonding device BD may be arranged on a straight line in the third direction DR3 to overlap on the plane. That is, a laser beam generated from the laser irradiator LS is irradiated in a direction toward the stage STG.

In one or more embodiments, the stage STG may be moved to a working position or a standby position by a separate rail, etc. For example, the stage STG may be moved forward and backward in the second direction DR2 but is not limited thereto.

The pressure member PM is arranged above the backplane substrate 110 and the light emitting element LE and is formed of a material that transmits light and may move in the up-and-down direction.

The pressure member PM may further include a beam-transmitting plate and a head transfer unit.

The beam-transmitting plate may be formed as a rectangular plane having a long side in the first direction DR1 and a short side in the second direction DR2 that intersects the first direction DR1. A corner where the long side in the first direction DR1 and the short side in the second direction DR2 meet may be formed at a right angle. The plane shape of the beam-transmitting plate is not limited to a square and may be formed as another polygon, circle, or oval.

The beam-transmitting plate may be formed of a rigid light-transmitting material and may be implemented as a base material that transmits a laser beam.

The base material of the beam-transmitting plate may be implemented as any beam-transmitting material. The base material of the beam transmitting plate may be made of, for example, materials such as tempered glass, quartz, acrylic, metal oxides or oxides of semi-metals, e.g. silicon oxide, aluminum oxide, etc. However, it is not limited thereto. In particular, in the case of quartz, a laser transmittance of 85% to 99% may be preferred.

The beam transmitting plate may include a chuck having an adsorption function on one surface. This adsorption feature enables the beam transmitting plate to adsorb and transfer a second bonding object (e.g., a light emitting element LE).

The head transfer unit moves the beam transmitting plate to a working position or a standby position. For example, the head transfer unit may lower or raise the beam transmitting plate, or move it left or right, and then lower or raise it.

Referring to FIGS. 12-13, the mask M may serve to expose the conductive bonding pattern CBP and the light emitting element LE and to cover an area of the backplane substrate 110 other than the conductive bonding pattern CBP and the light emitting element LE. The mask M may be a material that does not transmit a laser beam. For example, the mask M may be a pattern having light-blocking and/or reflective patterns. The thickness of the mask M is not particularly limited but may have a film thickness within a range of 80 nm to 180 nm. If it is too thin, it becomes difficult to obtain the desired light-blocking or reflective patterns, and if it is too thick, it becomes difficult to process the light-blocking pattern with high precision.

The mask M may be any material having light-blocking or reflective patterns but is not particularly limited to chromium (Cr), chromium oxynitride (CrON), chromium nitride (CrN), molybdenum silicide oxide (MoSiO), molybdenum silicide oxynitride (MoSiON), tantalum oxide (TaO), tantalum silicide oxide (TaSiO), and/or the like.

The mask M includes a plurality of openings M-OS that overlap with the conductive bonding pattern CBP and the light emitting element LE.

The laser beam may be transmitted through the openings M-OS. Thus, the openings M-OS may define a transmission area of the laser beam. Therefore, light irradiated from the laser irradiator LS passes through the openings M-OS of the mask M and is irradiated to the conductive bonding pattern CBP. While the conductive bonding pattern CBP is irradiated by the laser beam, the mask M may prevent the entire area of the backplane substrate 110 from being exposed to the laser beam and receiving thermal damage.

The laser irradiator LS may irradiate the laser in a desired direction. The laser irradiator LS may provide not only a point light source but also a surface light source. The laser irradiator LS is arranged on the pressure member PM and irradiates the laser beam LSB toward the conductive bonding pattern CBP.

For example, the laser irradiator LS may include a laser light source and an optical system.

The laser light source is a device that may generate laser light by energy supplied from the outside and may be configured to generate laser light such as, for example, a solid-state laser, such as a YAG laser, a ruby laser, a glass laser, a YVO4 laser, an LD laser, a fiber laser, a liquid laser, such as a pigment laser, a CO₂ laser, an excimer laser (ArF laser, KrF laser, XeCl laser, XeF laser, etc.), a gaseous laser, such as an Ar laser, a He—Ne laser, a semiconductor laser, a free-electron laser, etc.

The optical system may receive laser light in the form of a beam from the laser light source and perform optical dispersion so that area heating is possible for a suitable area (e.g., a predetermined area) (e.g., area heating is possible for a suitable area of the backplane substrate 110).

For example, the optical system may include a beam shaper and/or the like that converts the laser light in the form of a spot to an area light source. The optical system may further include a plurality of lens modules that are arranged below the beam shaper and spaced (e.g., spaced apart) from each other at suitable intervals within the cavity. The plurality of lens modules may be controlled such that a plane light source emitted from the beam shaper irradiates the irradiation area of the bonding objects WP1 and WP2.

The optical system may be raised or lowered along the third direction DR3 or moved left and right along the first direction DR1 or moved along the second direction DR2 for flatness adjustment and height adjustment with the bonding objects.

The laser beam LSB (e.g., see FIG. 18) emitted from the laser irradiator LS may be irradiated to the conductive bonding pattern CBP by passing through the pressure member PM and may heat a suitable area (e.g., a predetermined area). The laser light emitted from the optical system may have a wavelength range of about 250 nm to 5 μ. However, the present disclosure is not limited thereto.

In one or more embodiments, the temperature at which the conductive bonding pattern CBP is reflowed may be about 140° C. and the temperature at which it is cured may be about 240 140° C. to 280 140° C. Accordingly, the output of the laser light source and/or the like may be adjusted to account for this.

Thereby, the state of the conductive bonding pattern CBP may be changed to bond the light emitting element LE to the backplane substrate 110. The light emitting element LE is illustrated in the embodiment of FIGS. 8 and 11, but is not limited thereto, and may be applied to the integrated circuit IC or display driving circuit 250 described with reference to FIGS. 2 and 3.

The laser bonding device BD may further include a control portion CU.

The control portion CU controls the overall operation of the laser bonding device BD and each component. For example, the control portion CU controls the laser power and laser irradiation time of the laser generating portion of the laser irradiator LS.

Further, in one or more embodiments, the control portion CU may control the pressure applied to the pressure member PM according to the state.

The operation performed by the control portion CU may be distributed and processed by multiple physically separated computational devices. It is also possible that some of the operations performed by the control portion CU are performed by the first server and other operations are performed by the second server. In this case, the control portion CU may be implemented as a sum of physically separated computational devices.

The control portion CU according to an one or more embodiments of the present disclosure may be implemented by a non-volatile memory configured to store data concerning an algorithm configured to control the operations of various components of the laser bonding device BD or software instructions for reproducing the algorithm, and a processor configured to perform the operations described below using the data stored in the memory. The memory and the processor may be implemented as separate chips. Alternatively, the memory and the processor may be implemented as a single chip integrated with each other. The processor may take the form of one or more processors.

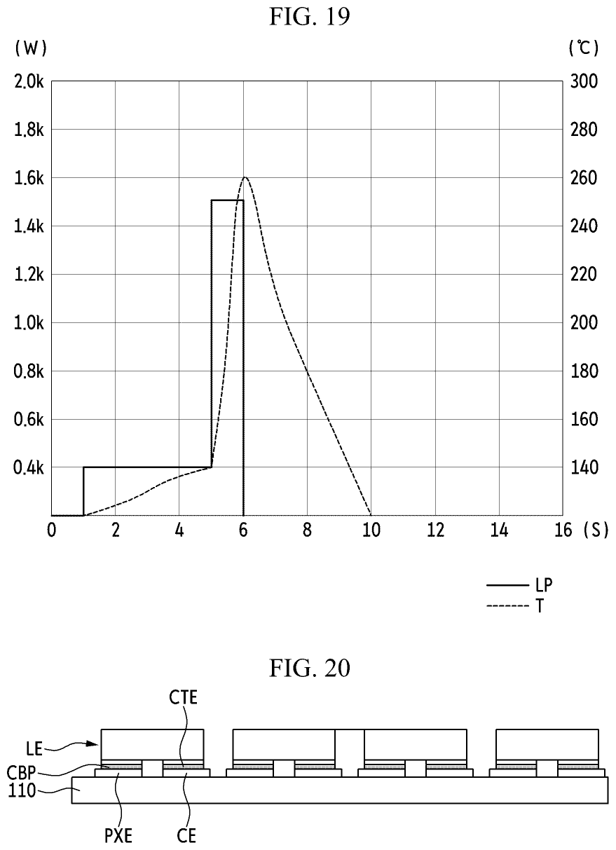

The laser bonding device BD according to one or more embodiments may control the temperature and pressure (e.g., in kilogram-force (kgf) or kilogram-force per square centimeter (kgf/cm²) ) of the heat applied according to the state of the bonding member by varying the laser power W and the irradiation time s (e.g., see FIG. 19) during the laser bonding process.

For example, the control portion CU of the laser bonding device BD may irradiate the laser with the first power for the first time and then irradiate the laser with the second power higher than the first power for the second time. The first irradiation and the second irradiation may be performed continuously. The temperature of the first irradiation may be the melting temperature of the polymer resin and may be about 140° C. The polymer resin of the conductive bonding pattern CBP may be melted to bond the light emitting element LE to the backplane substrate 110. The temperature of the second irradiation may be the temperature for forming an electrical network of nano-conductive particles such as carbon black and stabilizing the components inside the polymer resin and may be about 240 to 280 degrees Celsius (e.g., see FIG. 19).

The first time may be 4 seconds, the first power may be 600 W, the second time may be 2 seconds, and the second power may be 1400 W, but this may be changed depending on the performance of the laser irradiator LS (e.g., see FIG. 19).

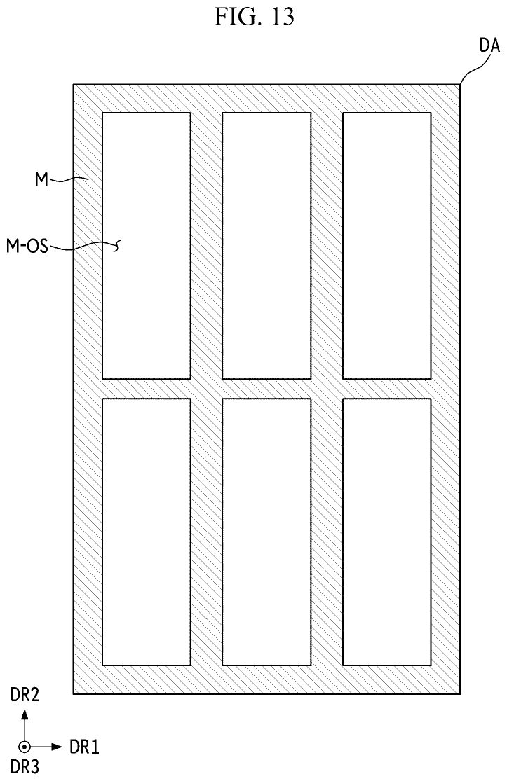

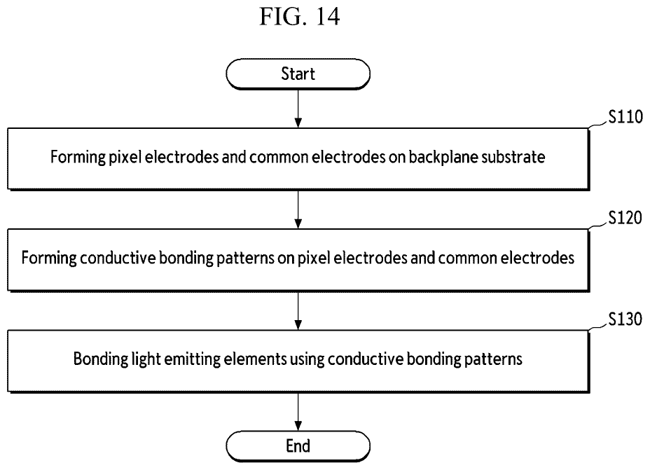

FIG. 14 is a method for illustrating a method for manufacturing a display device using a conductive bonding pattern.

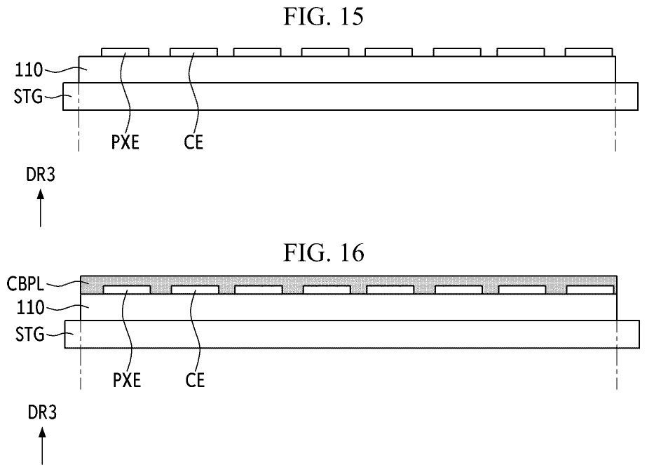

FIG. 15-18 and 20 are step-by-step cross-sectional views to illustrate a method for manufacturing a display device according to one or more embodiments. For example, FIG. 15-18 and 20 illustrate specific steps in cross-sectional views to illustrate a method for manufacturing a display device according to one or more embodiments. FIG. 19 is a graph illustrating laser power and laser temperature according to time of a laser bonding device according to one or more embodiments.

Hereinafter, a method for manufacturing a display device will be described with reference to FIG. 15-20 in consideration of FIG. 14.

The method for manufacturing a display device described with reference to FIG. 14-20 may be applied to a display device including a light emitting element and a display panel described with reference to FIG. 9-11. Further, the method for manufacturing a display device described with reference to FIG. 15-18 may be performed by a laser bonding device BD described with reference to FIG. 12.

Referring to FIG. 15, a plurality of pixel electrodes PXE and a common electrode CE may be formed on a backplane substrate 110. (S110 in FIG. 14)

For example, first, a conductive electrode material is deposited on a backplane substrate 110, and then a plurality of pixel electrodes PXE and a common electrode CE are formed through a patterning process.

The method of depositing the conductive electrode material may be formed using any method capable of forming a metal layer, such as a screen printing method or deposition and sputtering using an electron beam (E-Beam).

The patterning process may form a plurality of pixel electrodes PXE and a common electrode CE by applying a photoresist on a conductive electrode material, performing an exposure process to transfer a pattern onto the photoresist, and removing a portion other than the pattern through a development process.

The backplane substrate 110 may include a substrate SUB described in FIG. 7, and a thin film transistor layer TFTL.

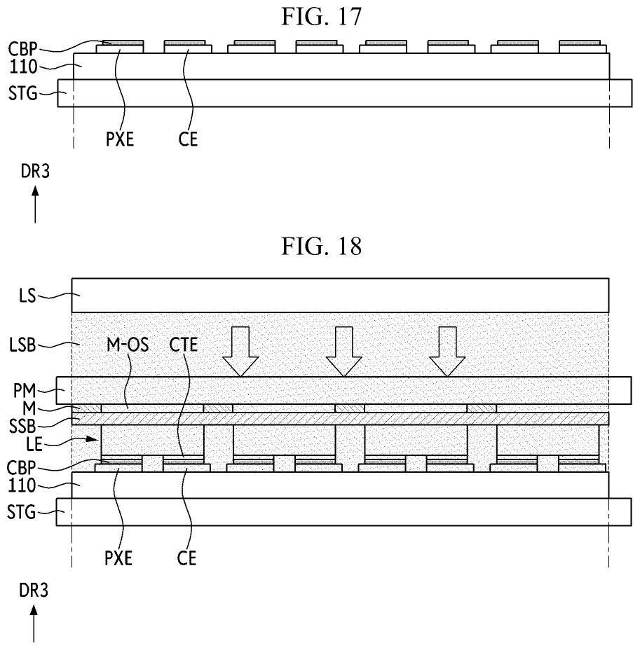

Referring to FIGS. 16 and 17, a conductive bonding pattern CBP is formed on each electrode of a plurality of pixel electrodes PXE and a common electrode CE pair. (S120 in FIG. 14)

To this end, a conductive bonding material CBPL including a polymer resin and conductive nanoparticles is applied to the entire surface of a backplane substrate 110, and then, through a patterning process, only the conductive bonding material CBPL in an area completely overlapping with the plurality of pixel electrodes PXE and the common electrode CE is left, and the rest is removed. Accordingly, a conductive bonding pattern CBP may be formed in an area overlapping with the plurality of pixel electrodes PXE and the common electrode CE.

Next, referring to FIG. 18, the laser bonding device BD applies heat to the conductive bonding pattern CBP to bond the light emitting element LE. (S130 in FIG. 14)

Although the light emitting element LE is illustrated in FIG. 18, the light emitting element LE may be any of the integrated circuit IC, sensor, and display driving circuits 250 described with reference to FIGS. 2 and 3, and any of the light emitting elements LE described with reference to FIG. 7 or 11.

For example, a backplane substrate 110 is placed on a stage STG.

The light emitting element LE is arranged to face the conductive bonding pattern CBP of the backplane substrate 110.

The light emitting element LE may be arranged on the second substrate SSB. The second substrate SSB may be a relay substrate.

The plurality of light emitting elements LE may be transferred onto a relay substrate by an electrostatic method using an electrostatic head or a stamp method using an elastic polymer material such as PDMS or silicone as a transfer substrate.

The relay substrate may be composed of a support layer and an adhesive layer arranged on the support layer. The support layer may be made of a material that is transparent and mechanically stable so that light may pass through it. For example, the support layer may include a transparent polymer such as polyester, polyacrylic, polyoxy, polyethylene, polystyrene, polyethylene terephthalate, and/or the like. The adhesive layer may include an adhesive material for bonding the light emitting elements LE. For example, the adhesive material may include urethane acrylate, epoxy acrylate, polyester acrylate, and the like. The adhesive material may be a material whose adhesive strength changes when ultraviolet (UV) light or heat is applied, and thus the adhesive layer may be easily separated from the light emitting elements LE.

A contact electrode CTE of the light emitting element LE is arranged so that it contacts the conductive bonding pattern CBP, and the pressure member PM is arranged on the second substrate SSB.

A mask M may be arranged between the second substrate SSB and the pressure member PM. The mask M may be a mask described with reference to FIGS. 12-13. The openings M_OS of the mask M may be arranged to overlap the light emitting element LE.

A laser irradiator LS may be arranged above the pressure member PM. First, the laser irradiator LS may irradiate the laser with a first power for a first time and then irradiate the laser with a second power higher than the first power for a second time. If the mask M is arranged between the second substrate SSB and the pressure member PM before the laser irradiation, the first irradiation and the second irradiation may be performed continuously.

During the laser irradiation, the pressure member PM pressurizes the light emitting element LE so that the height of the conductive bonding pad CBP becomes 1 μor less. The pressure member PM may pressurize at a pressure of about 5 MPa.

Referring to FIG. 19, the solid line of the graph represents the laser power, and the dotted line of the graph represents the temperature. The left vertical axis of the graph represents the laser power W, and the right vertical axis represents the temperature (° C .). The horizontal axis of the graph represents the laser irradiation time (seconds, S).

The laser irradiator LS irradiates a laser beam with a laser power of 400 W for 4 seconds to increase the temperature to 140° C. Then, a laser beam with a laser power of 1500 W is continuously irradiated for 2 seconds to increase the temperature to 260° C.

In one or more embodiments, the first laser irradiation may be performed without arranged the mask M between the second substrate SSB and the pressure member PM before the laser irradiation. The first laser irradiation may be performed without the mask M in place because, as described above, the first laser irradiation is performed at a relatively low temperature, and therefore, there is less risk of causing thermal damage to the backplane substrate 110. After the first laser irradiation, the mask M is arranged between the second substrate SSB and the pressure member PM, and the laser power is increased to perform the second laser irradiation. Because the second irradiation is performed at a relatively high temperature, the mask M may be used to prevent the entire area of the backplane substrate 110 from being exposed to the laser beam.

When the second laser irradiation is completed, the pressure member PM is raised, and the second substrate SSB is separated from the light emitting element LE and removed, as shown in FIG. 20.

As described above, the method of bonding elements by irradiating a laser on conductive nanoparticles may be completed in a short time (e.g., 6 seconds) from bonding to post-curing in one process by controlling the laser power. Further, because a mask is used, exposure of the backplane substrate to the laser beam may be reduced or minimized, thereby also reducing or minimizing heat damage.

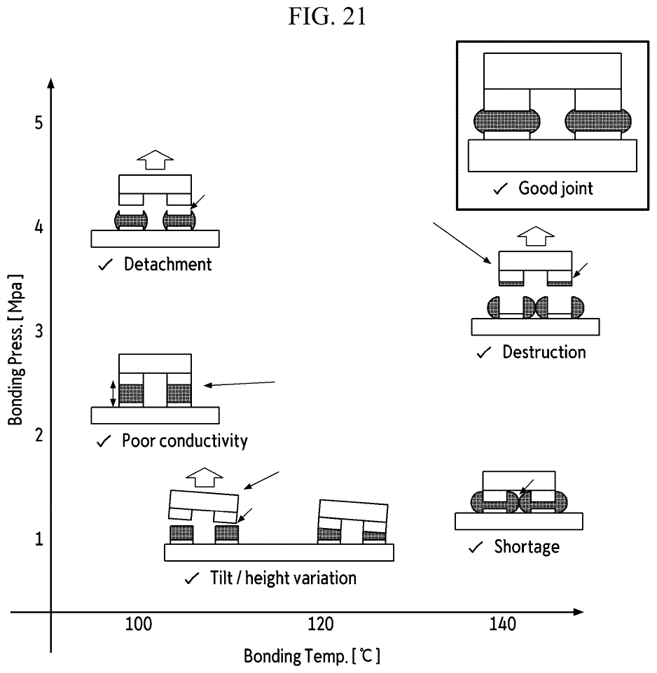

FIG. 21 is a diagram illustrating a bonding state according to bonding temperature and bonding pressure in a bonding process by a laser bonding device according to one or more embodiments.

First, in the laser bonding method described with reference to FIG. 15-21 according to one or more embodiments, the most preferable bonding temperature is 140° C., and the bonding pressure is 5 MPa.

When the bonding temperature is 100° C. to 120° C. and the bonding pressure is 1 MPa, the light emitting element may be tilted or shifted. When the bonding temperature is 140° C. and the bonding pressure is 1 MPa, the light emitting element may be bonded in a tilted or shifted state and may be short-circuited.

Next, when the bonding temperature is 100° C. and the bonding pressure is 2 MPa, the electrical network between the nanoparticles in the conductive nanoparticles may not be smoothly formed, which may result in poor conductivity.

Next, when the bonding temperature is 100° C. and the bonding pressure is 4 MPa, the light emitting element and the polymer resin in the conductive nanoparticles may not be sufficiently melted, which may result in the light emitting element being detached.

Next, when the bonding temperature is 140° C. and the bonding pressure is 3 to 4 MPa, the conductive nanoparticles may be destroyed.

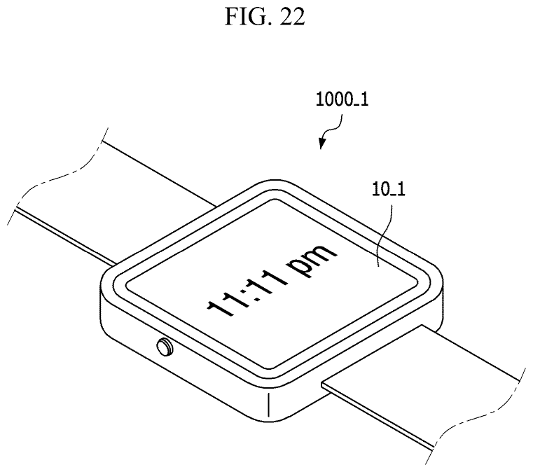

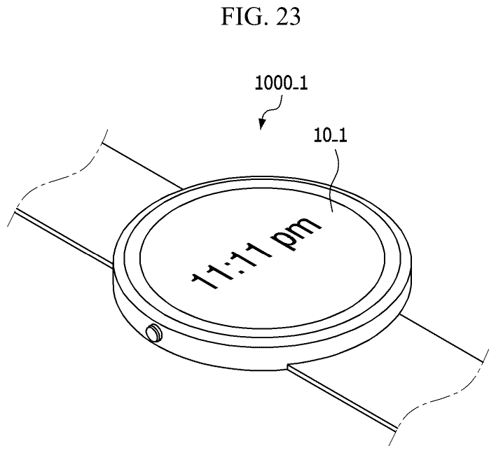

FIGS. 22 and 23 are example drawings illustrating a smart watch including a display device according to one or more embodiments.

Referring to FIGS. 22 and 23, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

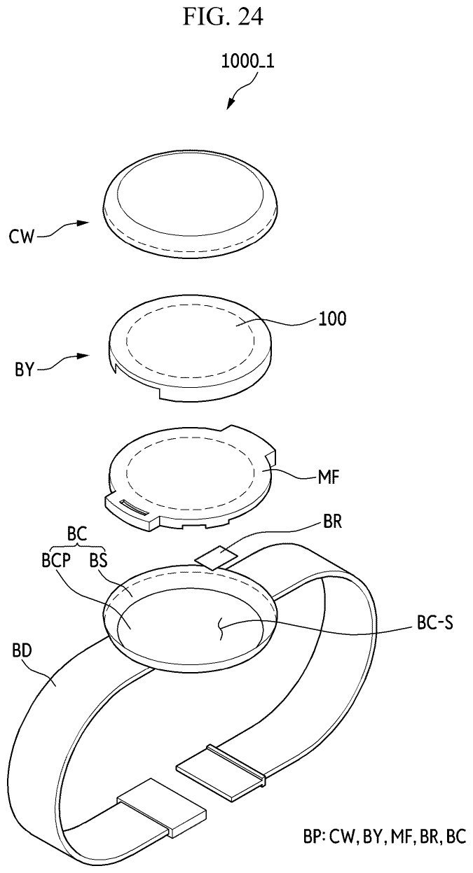

FIG. 24 is an exploded perspective view of a smart watch including a display device according to one or more embodiments.

Referring to FIG. 24, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body unit BP. For example, the planar shape of the cover window CW may be generally circular but is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to be around (e.g., to surround) the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a suitable curvature (e.g., a predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and/or the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

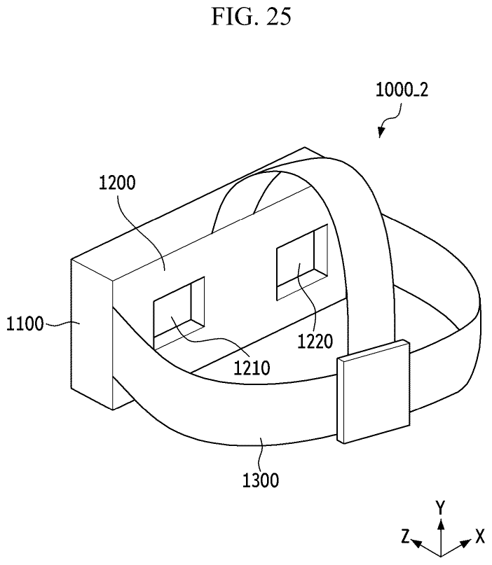

FIG. 25 is example views of a virtual reality (VR) device including a display device according to one or more embodiments.

Referring to FIG. 25, a head mounted display device 1000_2 according to one or more embodiments includes a display device housing 1100, a housing cover 1200, a first eyepiece 1210, a second eyepiece 1220, and head mounted band 1300.

The display device housing 1100 houses a display device. A head mounted display device 1000_2 according to one or more embodiments further include a first optical member disposed between the first display device and the first eyepiece 1210.

The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIG. 21, the present disclosure is not limited thereto. The first eyepiece 1210 and the second eyepiece 1220 may also be combined into one.

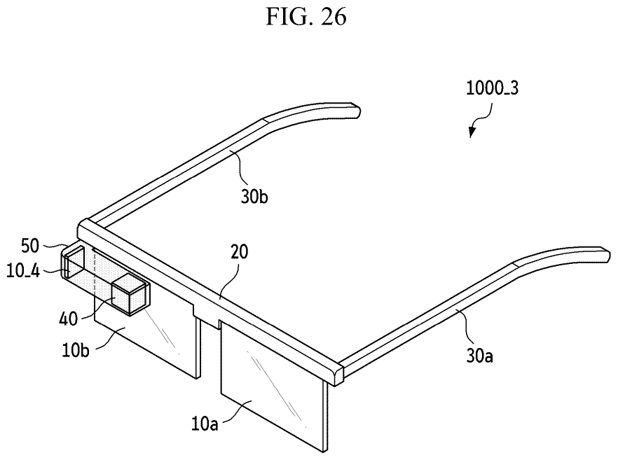

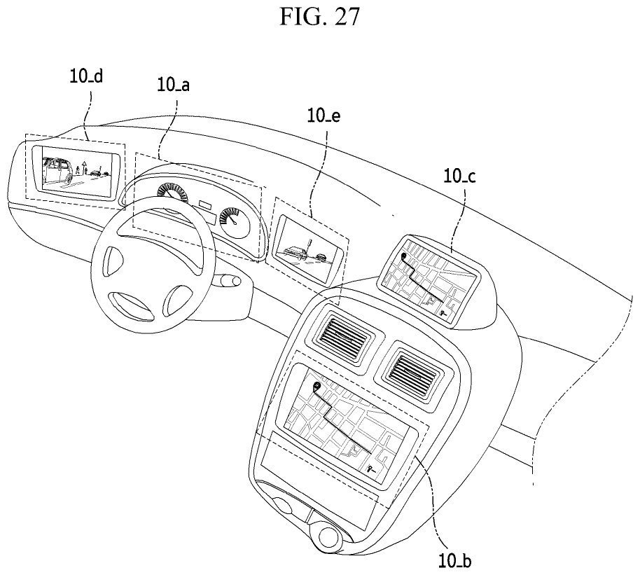

The head mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head mounted display device 1000_2 may include an eyeglass frame as illustrated in FIG. 26 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 26 is an example view of a VR device including a display device according to one or more embodiments. FIG. 26 illustrates a VR device 1000_3 to which a display device 10_4 according to one or more embodiments has been applied.

Referring to FIG. 26, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 26, a case where the VR device 1000_3 is a glasses-type display device including the eyeglass frame legs 30a and 30b is illustrated as an example. That is, the VR device 1000_3 according to the embodiment is not limited to the one illustrated in FIG. 26 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 26, the present disclosure is not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

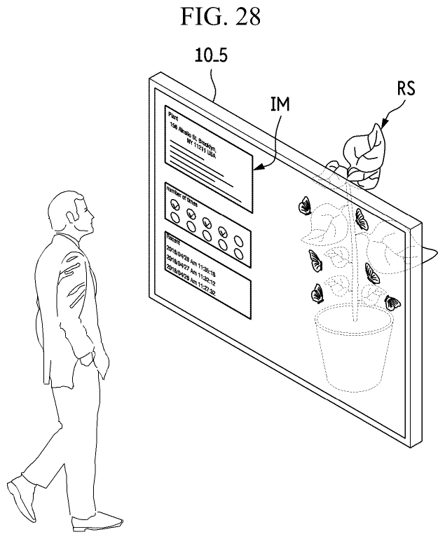

FIG. 27 is an example view illustrating a vehicle instrument cluster and center fascia including display devices according to one or more embodiments. FIG. 27 illustrates a vehicle to which display devices 10_a through 10_e according to one or more embodiments have been applied.

Referring to FIG. 27, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

FIG. 28 is an example view of a transparent display device including a display device according to one or more embodiments.

Referring to FIG. 28, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A laser bonding device comprising:
a stage configured to support a first substrate;
a pressure module configured to fix a plurality of elements on the first substrate;
a laser irradiator configured to irradiate a laser beam to a conductive bonding pattern located between the first substrate and the plurality of elements; and
a mask located on the first substrate and having openings overlapping the plurality of elements,
wherein the plurality of elements comprises at least one of a light emitting element, an integrated circuit, or a driving circuit, and
wherein the laser irradiator is configured to irradiate a laser beam of a first power for a first time period and configured to irradiate a laser beam of a second power higher than the first power for a second time period.

2. The device of claim 1, wherein the conductive bonding pattern comprises a polymer resin and conductive nanoparticles dispersed in the polymer resin.

3. The device of claim 2, wherein the conductive nanoparticles comprise a conductive carbon black.

4. The device of claim 1, wherein a height of the conductive bonding pattern is 1 μm or less.

5. The device of claim 1, wherein the mask comprises a light-blocking or a reflective material in an area other than the openings.

6. The device of claim 1, wherein the laser irradiator is configured to perform area heating for an area of the first substrate.

7. The device of claim 1, wherein the laser irradiator is configured to irradiate the laser beam of the first power for the first time period to have a process temperature of 140°C, and configured to irradiate the laser beam of the second power for the second time period to have the process temperature of 260° C.

8. The device of claim 1, wherein a first electrode is on the first substrate, and the conductive bonding pattern is on the first electrode, and
wherein the openings of the mask overlap the conductive bonding pattern.

9. The device of claim 1, wherein the light emitting element comprises a contact electrode on one surface, and a plurality of semiconductor layers on the contact electrode,
wherein the contact electrode is on the conductive bonding pattern and electrically connected to the conductive bonding pattern.

10. A laser bonding method comprising:
forming a first electrode on a first substrate;
forming a conductive bonding pattern on the first electrode; and
arranging an element of a plurality of elements on the conductive bonding pattern, the plurality of elements comprising at least one of a light emitting element, an integrated circuit, or a driving circuit;
irradiating the conductive bonding pattern with a laser beam of a first power for a first time period, and irradiating the conductive bonding pattern with a laser beam of a second power higher than the first power for a second time period, and
arranging a mask having openings overlapping the plurality of elements on the first substrate before irradiating the laser beam of the second power higher than the first power for the second time period.

11. The method of claim 10, wherein the conductive bonding pattern comprises a polymer resin and conductive nanoparticles dispersed in the polymer resin.

12. The method of claim 11, wherein the conductive nanoparticles comprise a conductive carbon black.

13. The method of claim 10, wherein, the forming the conductive bonding pattern comprises applying a conductive bonding material to an entire surface of the first substrate covering the first electrode and patterning the conductive bonding pattern using a photolithography process using the mask.

14. The method of claim 11, wherein a pressure member is located between a laser irradiator and the light emitting element and configured to pressurize the light emitting element to 5 MPa while irradiating the laser beam.

15. The method of claim 14, wherein the pressure member is configured to pressurize the conductive bonding pattern until a height of each of the conductive bonding pattern is 1 μmor less.

16. The method of claim 10, wherein the mask comprises a light-blocking or a reflective material in an area other than the openings.

17. The method of claim 10, wherein the laser irradiator is configured to perform area heating for an area of the first substrate.

18. The method of claim 10, wherein the laser irradiator is configured to irradiate the laser beam of the first power for the first time period to have a process temperature of 140° C., and configured to irradiate the laser beam of the second power for the second time period to have the process temperature of 260° C.

19. The method of claim 10, wherein the arranging the element on the conductive bonding pattern comprises arranging the light emitting element on a second substrate,
wherein a contact electrode of the light emitting element faces the conductive bonding pattern, and
wherein, after the laser irradiation is completed, the second substrate is separated and removed from the light emitting element.

20. An electronic device comprising a laser bonding device, the laser bonding device comprising:
a stage configured to support a first substrate;
a pressure module configured to fix a plurality of elements on the first substrate;
a laser irradiator configured to irradiate a laser beam to a conductive bonding pattern located between the first substrate and the plurality of elements; and
a mask located on the first substrate and having openings overlapping the plurality of elements,
wherein the plurality of elements comprises at least one of a light emitting element, an integrated circuit, or a driving circuit, and
wherein the laser irradiator is configured to irradiate a laser beam of a first power for a first time period and configured to irradiate a laser beam of a second power higher than the first power for a second time period.
